(19) United States
(12) Patent Application Publication
(10) Pub. No.: US 2002/0086456 A1
(43) Pub. Date: Jul. 4, 2002

(54) Bulk micromachining process for fabricating an optical MEMS device with integrated optical aperture

(76) Inventors: Shawn Jay Cunningham, Colorado Springs, CO (US); Svetlana Tacic-Lucic, Colorado Springs, CO (US); Dana R. DeReus, Colorado Springs, CO (US)

Correspondence Address: JENKINS & WILSON, PA, 3100 TOWER BLVD, SUITE 1400, DURHAM, NC, 27707, US

(21) Appl. No.: 10/025,181

(22) Filed: Dec. 19, 2001

Related U.S. Application Data
(60) Provisional application No. 60/256,604, filed on Dec. 19, 2000.
(60) Provisional application No. 60/256,607, filed on Dec. 19, 2000.
(60) Provisional application No. 60/256,610, filed on Dec. 19, 2000.
(60) Provisional application No. 60/256,611, filed on Dec. 19, 2000.
(60) Provisional application No. 60/256,683, filed on Dec. 19, 2000.
(60) Provisional application No. 60/256,688, filed on Dec. 19, 2000.
(60) Provisional application No. 60/256,689, filed on Dec. 19, 2000.
(60) Provisional application No. 60/256,674, filed on Dec. 20, 2000.
(60) Provisional application No. 60/260,558, filed on Jan. 9, 2001.

(51) Int. Cl. H01L 21/00

(52) U.S. Cl. 438/57

(57) ABSTRACT

An optical MEMS device is fabricated by forming and aperture through the thickness of a first substrate to enable an optical signal to be transmitted through the aperture. A movable, actuatable microstructure is formed on a second substrate. The second substrate is bonded to the first substrate. The first and second substrates are aligned to enable the microstructure to interact with the optical signal upon actuation of the microstructure. A conductive element is formed on the first substrate to serve as a contact or an interconnect. A channel is formed in the second substrate. An insulating layer can be deposited on the inside surfaces of this channel. When the first and second substrates are bonded together, the conductive element formed on the first substrate is disposed within the channel and is isolated from conductive regions of the resulting optical MEMS device. In another method, an optical MEMS device is fabricated from a substrate that comprises an etch-stop layer interposed between first and second bulk layers. The movable, actuatable microstructure is formed into the first bulk layer, and the aperture is formed through the second bulk layer.

### RELATED APPLICATIONS

This application claims the benefit of U.S. Provisional Patent Application Serial Nos. 60/256,604, filed Dec. 19, 2000; 60/256,607, filed Dec. 19, 2000; 60/256,610, filed Dec. 19, 2000; 60/256,611 filed Dec. 19, 2000; 60/256,683, filed Dec. 19, 2000; 60/256,688 filed Dec. 19, 2000; 60/256,689, filed Dec. 19, 2000; 60/256,674, filed Dec. 20, 2000; and 60/260,558, filed Jan. 9, 2001, the disclosure of which is incorporated herein by reference in its entirety.

### TECHNICAL FIELD

The present invention generally relates to MEMS fabrication technology. More specifically, the present invention relates to methods for fabricating optical apertures exhibiting low light losses in wafers as an integral part of a method for fabricating a through-wafer optical MEMS device.

### BACKGROUND ART

Micro-optical-electro-mechanical systems (MO EMS, or optical ME MS) are being investigated and developed for their potential to improve optics-based systems, such as CDMA encoders and decoders, by reducing the cost and component size of such systems as well as to increase their functionality and programmability. In particular, optical shutters and other types of microstructures are being considered as means for interacting with an optical path to implement switching or attenuating functions. Shutter architectures can be based on either through-die or across-die solutions. In through-die architectures, the shutter can be actuated to interrupt an optical path from passing through the thickness of a wafer, whereas in across-die architectures, a shutter can be actuated to interrupt an optical path from passing across a surface of a wafer.

As appreciated by persons skilled in the art, many types of MEMS structures and devices can be fabricated by either bulk or surface micromachining techniques. Bulk micromachining generally involves sculpting one or more sides of a substrate to form desired three-dimensional structures and devices in the same substrate material. The substrate is composed of a material that is readily available in bulk form, and thus ordinarily is silicon or glass. Wet and/or dry etching techniques are employed in association with etch masks and etch stops to form the microstructures. Etching is typically performed through the backside of the substrate. The etching technique can generally be either isotropic or anisotropic in nature. Isotropic etching is insensitive to the crystal orientation of the planes of the material being etched (e.g., the etching of silicon by using a nitric acid as the etchant). Anisotropic etchants, such as potassium hydroxide (KOH), tetramethyl ammonium hydroxide (TMAH), and ethylenediamine pyrochatechol (EDP), selectively attack different crystallographic orientations (e.g., <100> and <111>) at different rates, and thus can be used to define relatively accurate sidewalls in the etch pits being created. Etch masks and etch stops are used to prevent predetermined regions of the substrate from being etched.

Surface micromachining, on the other hand, generally involves forming three-dimensional structures by depositing a number of different thin films on the top of a silicon wafer, but without sculpting the wafer itself. The films usually serve as either structural or sacrificial layers. Structural layers are frequently composed of polysilicon, silicon nitride, silicon dioxide, silicon carbide, or aluminum. Sacrificial layers are frequently composed of polysilicon, photoresist material, or various kinds of oxides, such as PSG (phosphosilicate glass) and LTO (low-temperature oxide). Successive deposition, etching, and patterning procedures are carried out to arrive at the desired microstructure. In a typical surface micromachining process, a silicon substrate is coated with an isolation layer, and a sacrificial layer is deposited on the coated substrate. Windows are opened in the sacrificial layer, and a structural layer is then deposited and etched. The sacrificial layer is then selectively etched to form a free-standing microstructure such as a beam or a cantilever out of the structural layer. The microstructure is ordinarily anchored to the silicon substrate, and can be designed to be movable in response to an input from an appropriate actuating mechanism.

An example of a micromachining process for fabricating a MEMS VOA is disclosed in U.S. Pat. No. 6,275,320. A base substrate is provided that consists of a single-crystal silicon substrate on which an oxide layer and an upper single-crystal silicon layer are formed. The upper silicon layer is then patterned using a mask to define a MEMS actuator, optical shutter, and other actuator and attenuator components. A dry etch process is used to remove regions of the upper silicon layer to form the components. A time-dependent wet etch process is used to remove the oxide layer and release the components, but not the shutter. A doping process is then implemented to render one or more of the components conductive. Surfaces of the shutter are metallized to provide a mirror capable of deflecting an optical beam. A backside etch process is then used to etch through the silicon base substrate and the remaining oxide layer, thereby releasing the shutter.

It is acknowledged within the art that there remains an ongoing need for further improvements in bulk micromachining techniques for fabricating through-die architectures.

### DISCLOSURE OF THE INVENTION

The present invention provides a method for fabricating a through-wafer optical MEMS device such as a movable shutter assembly, wherein optical signals (i.e., light) pass through the wafer with low losses by means of an optical aperture formed in a bulk substrate or layer of the assembly when permitted to do so by the device. The resulting device transmits light efficiently because no light is absorbed in the substrate. The device exhibits an optical system architecture in which the optical information passes through the substrate without relying on antireflective coatings, highly transmissive materials, or wide optical bandwidth materials. The distance traveled in free space by optical information is shorter in comparison to previous solutions. According to the invention, the optical aperture is formed as part of the overall optical MEMS fabrication process flow as demonstrated by examples described in detail below, and thus is less costly and more efficient than previously developed processes.

The method of the present invention encompasses fabricating a through-wafer optical MEMS device by forming a movable, actuatable microstructure and an optical aperture, utilizing one or more starting substrates, through a novel combination of material-adding, masking, patterning, and etching steps generally available in the IC and/or MEMS industries. In addition, known doping techniques such as diffusion and ion implantation can be used to render certain desired structural layers of the invention conductive, when it is desired to utilize such layers as, for example actuation electrodes, contacts, or interconnects.

The substrate or bulk layer in which the optical aperture is to be formed can be any number of structural materials generally considered suitable in micromachining processes. Suitable examples include glass, quartz, sapphire, zinc oxide, silicon (in single-crystal, polycrystalline or amorphous forms), silica, alumina, or one of the various Group III-V compounds in either binary, ternary or quaternary forms (e.g., GaAs, InP, GaN, AlN, AlGan, InGaAs, and so on). These materials can also be selected for the substrate or structural layers used to form a microstructure over the aperture in accordance with the invention.

Silicon is readily available in boule or wafer form from commercial sources. The conductivity of the silicon layer or layers can be modulated by performing known methods of impurity doping. The various forms of silicon oxides (e.g., SiO₂, SiOₓ, and silicate glass) can be used as structural, insulating, or etch-stop layers. As known in the art, these oxides can be preferentially etched in hydrofluoric acid (HF) to form desired profiles. Various methods for adding oxide material to a substrate are known in the art. For example, silicon dioxide can be thermally grown by oxidizing silicon at high temperatures, in either a dry or wet oxidation process. Oxides and glasses, including phosphosilicate glass (PSG), borosilicate glass (BSG), borophosphosilicate glass (BPSG, also termed low-temperature oxide or LTO), as well as silicon-based thin films, can be deposited by chemical vapor deposition (CVD), including atmospheric pressure CVD (APCVD), low-pressure CVD (LPCVD) and low-temperature plasma-enhanced CVD (PECVD), as well as by physical vapor deposition (PVD) such as sputtering, or in some cases by a spin-on process similar to that used to deposit polymers and photoresists. Both stoichiometric and non-stoichiometric silicon nitride (SiₓN_{y}) can used as an insulating film, or as a masking layer in conjunction with an alkaline etch solution, and is ordinarily deposited by a suitable CVD method.

Contacts, interconnects, and light reflectors of various metals formed according to the methods of the invention are typically deposited by sputtering, CVD, or evaporation. If gold, nickel or Permalloy™ (NiₓFe_{y}) is selected as the metal element, an electroplating process can be carried out to transport the material to a desired surface. The chemical solutions used in the electroplating of various metals are generally known. Some metals, such as gold, might require an appropriate intermediate adhesion layer to prevent peeling. Examples of adhesion material often used include chromium, titanium, or an alloy such as titanium-tungsten (TiW).

Conventional lithographic techniques can be employed in accordance with the micromachining steps of the invention. Accordingly, basic lithographic process steps such as photoresist application, optical exposure, and the use of developers are not described in detail herein.

Similarly, generally known etching processes can be employed in accordance with the invention to selectively remove material or regions of material. An imaged photoresist layer is ordinarily used as a masking template. A pattern can be etched directly into the bulk of a substrate, or into a thin film or layer that is then used as a mask for subsequent etching steps.

As appreciated by those skilled in the art, the type of etching process employed in a particular process step described hereinbelow (e.g., wet, dry, isotropic, anisotropic, anisotropic-orientation dependent), the etch rate and the type of etchant used, will depend on the composition of material to be removed, the composition of any masking or etch-stop layer to be used, and the profile of the etched region to be formed. As examples, poly-etch (HF:HNO₃:CH₃COOH) can generally be used for isotropic wet etching. Hydroxides of alkali metals (e.g., KOH), simple ammonium hydroxide (NH₄OH), quaternary (tetramethyl) ammonium hydroxide ((CH₃)₄NOH, also known commercially as TMAH), and ethylenediamine mixed with pyrochatechol in water (EDP) can be used for anisotropic wet etching to fabricate V-shaped or tapered grooves, trenches or cavities. Silicon nitride is typically used as the masking material against etching by KOH, and thus can used in conjunction with the selective etching of silicon. Silicon dioxide is slowly etched by KOH, and thus can be used as a masking layer if the etch time is short. While KOH will etch undoped silicon, heavily doped (p++) silicon can be used as an etch-stop against KOH as well as the alkaline etchants and EDP. Silicon oxide and silicon nitride can be used as masks against TMAH and EDP. The preferred metal used to form contacts and interconnects in accordance with the invention is gold, which is resistant to EDP. The adhesion layer applied in connection with forming a gold component (e.g., chromium) is also resistant to EDP.

It will be appreciated that electrochemical etching in hydroxide solution can be performed instead of timed wet etching. For example, if a p-type silicon wafer is used as a substrate, an etch-stop can be created by epitaxially growing an n-type silicon end layer to form a p-n junction diode. A voltage is applied between the n-type layer and an electrode disposed in the solution to reverse-bias the p-n junction. As a result, the bulk p-type silicon is etched through a mask down to the p-n junction, stopping at the n-type layer. Also suitable are the more recently developed photovoltaic and galvanic etch-stop techniques, which are also based on the use of p-n junctions.

In addition, dry etching techniques such as plasma-phase etching and reactive ion etching (RIE) can be used to remove silicon and its oxides and nitrides, as well as various metals. Deep reactive ion etching (DRIE) can be used to anisotropically etch deep, vertical trenches in bulk layers. Silicon dioxide is typically used as an etch-stop against DRIE, and thus structures containing a buried silicon dioxide layer, such as silicon-on-insulator (SOI) wafers, can be used according to the methods of the invention as starting substrates for the fabrication of microstructures. Finally, the optical aperture or apertures formed as part of the methods of the invention could also be etched by a known ultrasonic drilling technique.

According to the first two exemplary methods of the invention described hereinbelow, a first substrate is used to fabricate one or more optical apertures, a second substrate is used to fabricate one or more microstructures to interact with optical signals directed through the apertures, and the two substrates are at some stage bonded together to complete an optical MEMS device. A number of different bonding techniques can be implemented for this purpose. For example, anodic bonding can be used to join a silicon substrate to many types of glass substrates, as well as to join glass-to-glass and silicon-to-silicon. Fusion bonding can be used to join two silicon substrates. In bonding silicon-to-silicon by either fusion bonding or anodic bonding, an intermediate silicon dioxide layer is normally interposed between the two silicon substrates. Hence, SOI starting wafers are typically produced by fusion bonding. In accordance with the invention, one of the silicon bulk layers of an SOI starting wafer can, after micromachining steps are performed to partially or completely form a microstructure, be bonded to a second, aperture-containing silicon wafer through the use of fusion bonding. Other suitable bonding techniques include glass-frit bonding (low-temperature glass bonding of silicon-to-silicon, with a boron glass interlayer), eutectic bonding (silicon-to-silicon, with a gold interlayer), and adhesive bonding (e.g., the gluing of silicon-to-silicon, silicon-to-glass, or glass-to-glass, using spin-on adhesives). Since many types of bonding techniques are successful only at a high bonding temperature, the choice of a suitable technique might be limited if certain metallization steps are carried out prior to the bonding step. Otherwise, the bonding step should be conducted before the forming of metal components when possible. In order to align one substrate to another substrate so that a microstructure can properly interface with an aperture, conventional precision alignment techniques (e.g., the use of spacers and clamping fixtures) can be employed if needed.

According to one method of the present invention, an optical MEMS device is fabricated according to the following steps. A first substrate is provided that has a first side and an opposing second side. An aperture is formed through the first substrate to enable an optical signal to be transmitted through the aperture along a path generally perpendicular to the first and second sides. A movable, actuatable microstructure is formed on a second substrate. The second substrate is bonded to the first substrate. The first and second substrates are aligned to enable the microstructure to interact with the optical signal upon actuation of the microstructure.

According to one aspect of this method, a conductive element is formed on the first substrate to serve as a contact or an interconnect. A channel is formed in the second substrate. An insulating layer can be deposited on the inside surfaces of this channel. When the first and second substrates are bonded together, the conductive element formed on the first substrate is disposed within the channel and is isolated from conductive regions of the resulting optical MEMS device.

According to another method of the present invention, an optical MEMS device is fabricated by the following steps. A substrate is provided that comprises an etch-stop layer interposed between first and second bulk layers. A movable, actuatable microstructure is formed into the first bulk layer. An aperture is formed through the second bulk layer to enable an optical signal to be transmitted through the aperture along a path generally perpendicular to the substrate. At least a portion of the etch-stop layer is removed. The amount of the etch-stop layer removed is sufficient to release the microstructure, thereby enabling the microstructure to interact with the optical signal upon actuation of the microstructure.

According to yet another method of the present invention, an optical MEMS device is fabricated by the following steps. A first substrate is provided that has a first side and an opposing second side. An aperture is formed through the first substrate to enable an optical signal to be transmitted through the aperture along a path generally perpendicular to the first and second sides. A movable, actuatable microstructure is formed from a second substrate. A conductive component is formed on the second substrate. A gap is formed in the second substrate to electrically isolate the conductive component from the microstructure. The second substrate bonding to the first substrate, whereby the first and second substrates are aligned to enable the microstructure to interact with the optical signal upon actuation of the microstructure.

The present invention also provides optical MEMS devices that are fabricated according to the methods of the present invention as described and claimed herein.

It is therefore an object of the present invention to provide a method for fabricating an optical MEMS device in which an optical aperture is fabricated in a substrate as part of the overall bulk micromachining process.

It is another object of the present invention to provide a method for fabricating an optical MEMS device that includes an integral process step wherein a low-loss optical aperture is formed, and wherein transmission of an optical signal through the device does not require anti-reflective coatings or highly transmissive substrate materials.

Some of the objects of the invention having been stated hereinabove and which are achieved in whole or in part by the present invention, other objects will become evident as the description proceeds when taken in connection with the accompanying drawings as best described hereinbelow.

### BRIEF DESCRIPTION OF THE DRAWINGS

FIGS. 1A and 1B are cross-sectional views of an optical aperture-containing substrate during various stages of the fabrication process according to a first method of the present invention;

FIGS. 2A-2I are cross-sectional views of a microstructure-containing substrate during various stages of the fabrication process according to the first method of the present invention;

FIGS. 3A-3D are cross-sectional views of an optical MEMS device during various stages of the fabrication process thereof, including the bonding of the substrate illustrated in FIGS. 1A and 1B to the substrate illustrated in FIGS. 2A-2I according to the first method of the present invention;

FIGS. 4A and 4B are cross-sectional views of an optical aperture-containing substrate during various stages of the fabrication process thereof, according to a second method of the present invention;

FIGS. 5A-5L are cross-sectional views of a microstructure-containing substrate during various stages of the fabrication process, according to the second method of the present invention;

FIGS. 6A-6D are cross-sectional views of an optical MEMS device during various stages of the fabrication process thereof, including the bonding of the substrate illustrated in FIGS. 4A and 4B to the substrate illustrated in FIGS. 5A-5L, according to the second method of the present invention;

FIGS. 7A-7H are cross-sectional views of an optical MEMS device during various stages of the fabrication process thereof, according to a third method of the present invention;

FIG. 8 is a cross-sectional view of an optical MEMS device fabricated according to any of the methods of the present invention;

FIGS. 9A and 9B are cross-sectional views of an optical aperture-containing substrate during various stages of the fabrication process according to an additional method of the present invention;

FIGS. 10A-10H are cross-sectional views of a microstructure-containing substrate during various stages of the fabrication process in connection with the method illustrated in FIGS. 9A and 9B; and

FIGS. 11A-11D are cross-sectional views of an optical MEMS device during various stages of the fabrication process thereof, including the bonding of the substrate illustrated in FIGS. 9A and 9B to the substrate illustrated in FIGS. 10A-10H.

### DETAILED DESCRIPTION OF THE INVENTION

For purposes of the present disclosure, it will be understood that when a given component such as a layer, region or substrate is referred to herein as being disposed or formed “on” another component, that given component can be directly on the other component or, alternatively, intervening components (for example, one or more buffer or transition layers, interlayers, electrodes or contacts) can also be present. It will be further understood that the terms “disposed on” and “formed on” are used interchangeably to describe how a given component is positioned or situated in relation to another component. Hence, the terms “disposed on” and “formed on” are not intended to introduce any limitations relating to particular methods of material transport, deposition, or fabrication.

Terms relating to crystallographic orientations, such as Miller indices and angles in relation to the plane of a layer of material, are intended herein to cover not only the exact value specified (e.g., (116), 45° and so on) but also any small deviations from such exact value that might be observed.

As used herein, the term “epitaxy” generally refers to the formation of a single-crystal film structure on top of a crystalline substrate, and could encompass both homoepitaxy and heteroepitaxy.

As used herein, the term “device” is interpreted to have a meaning interchangeable with the term “component.”

As used herein, the term “conductive” is generally taken to encompass both conducting and semi-conducting materials.

Examples of the methods of the present invention will now be described with reference to the accompanying drawings.

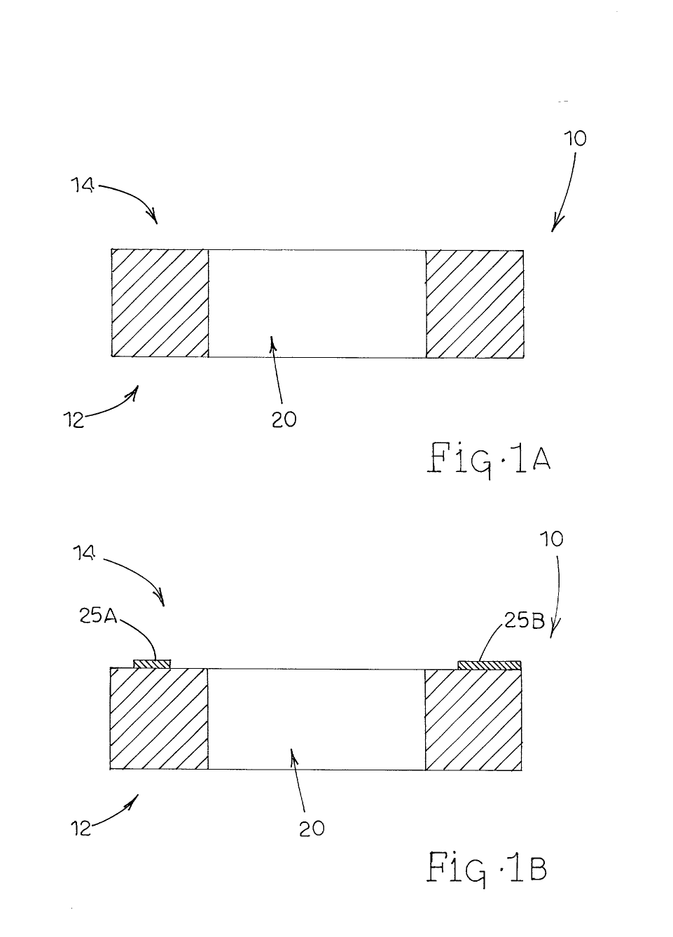

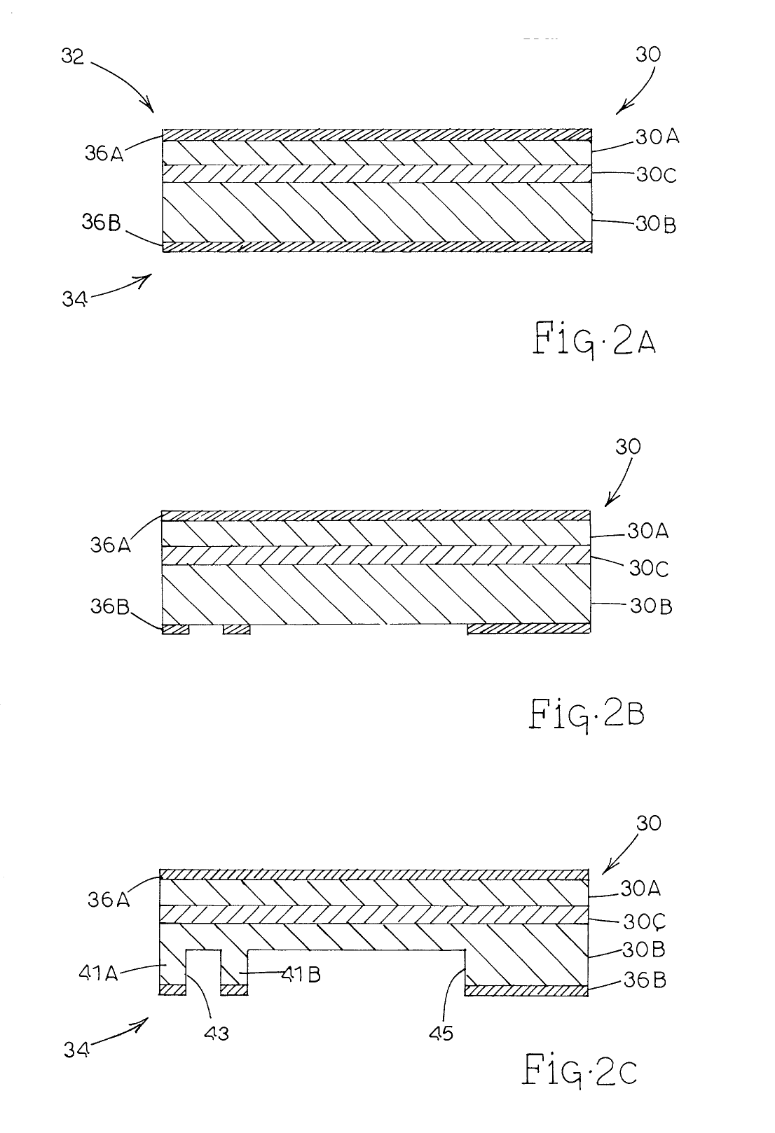

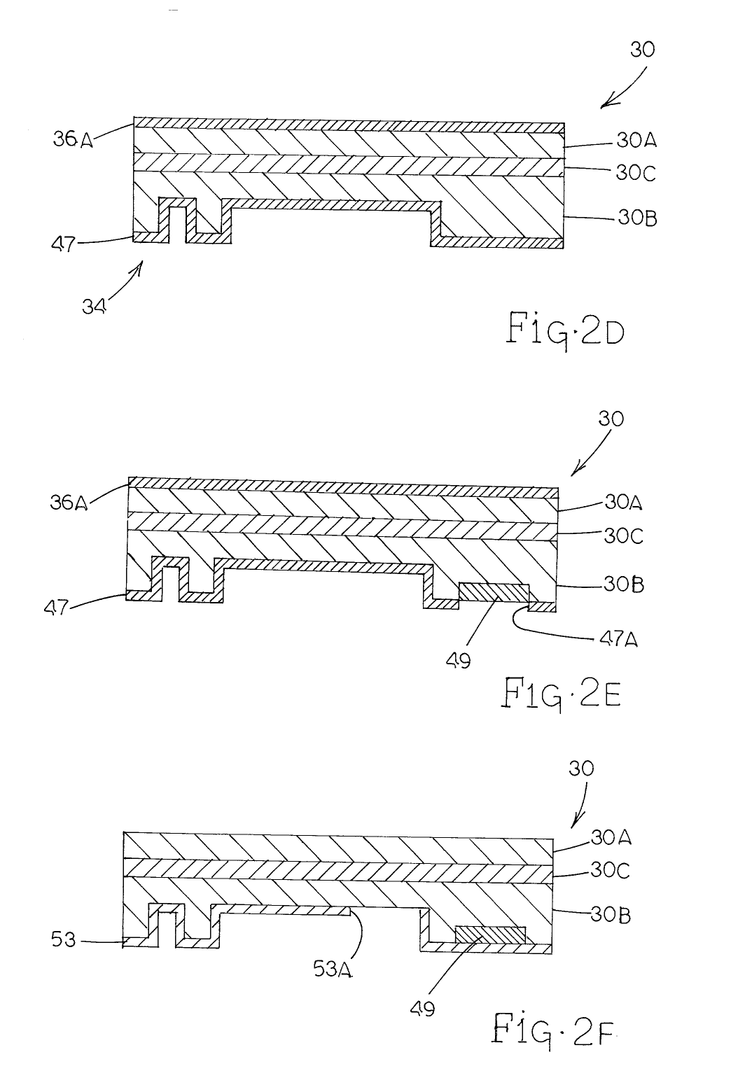

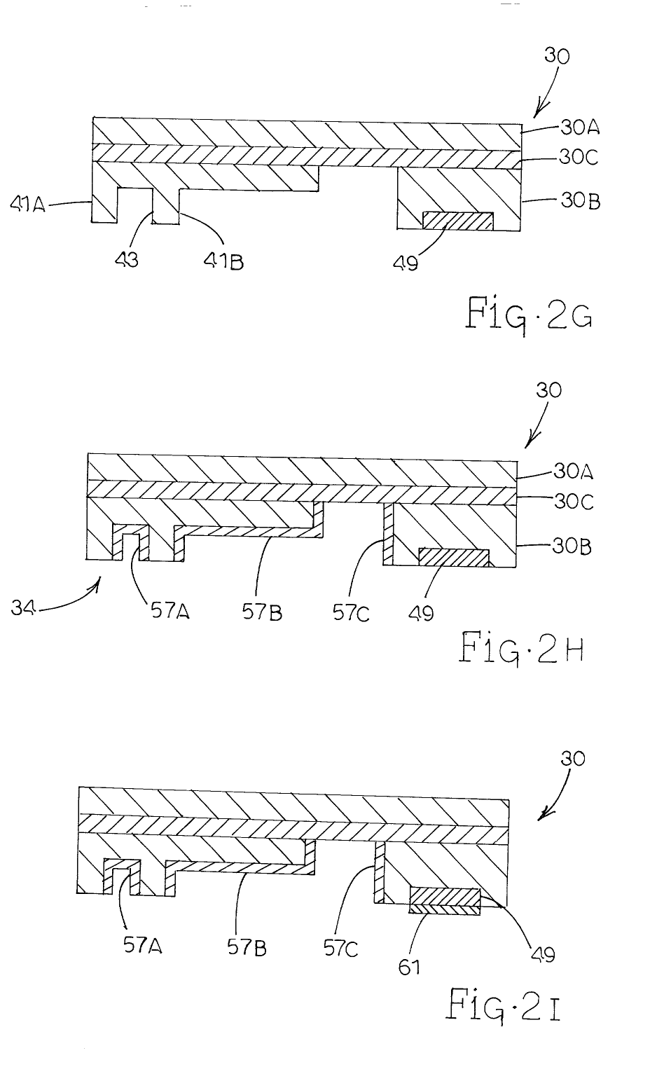

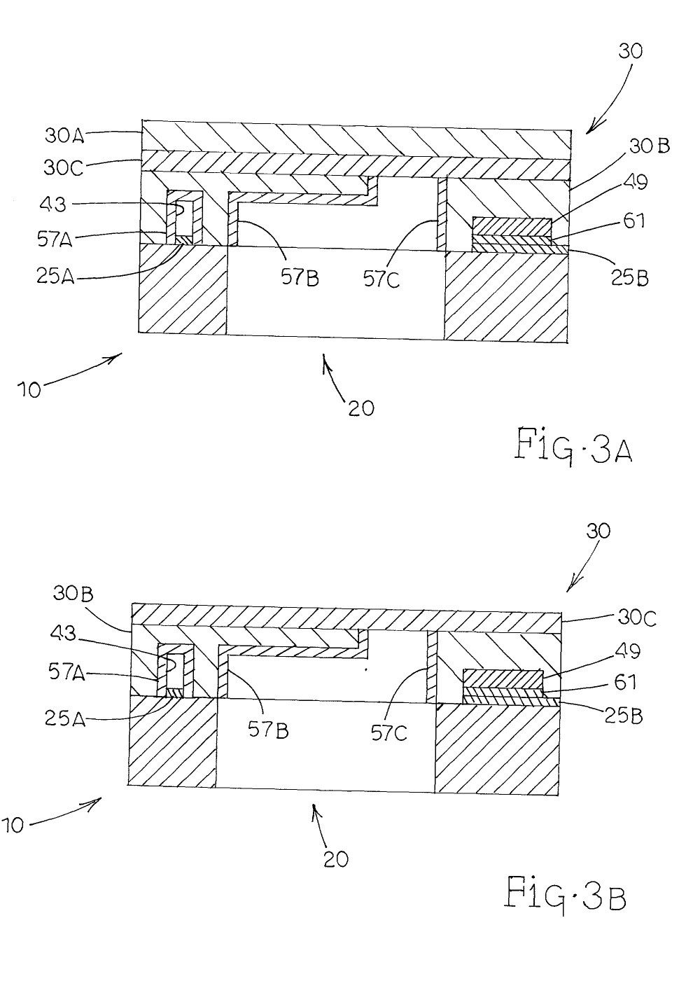

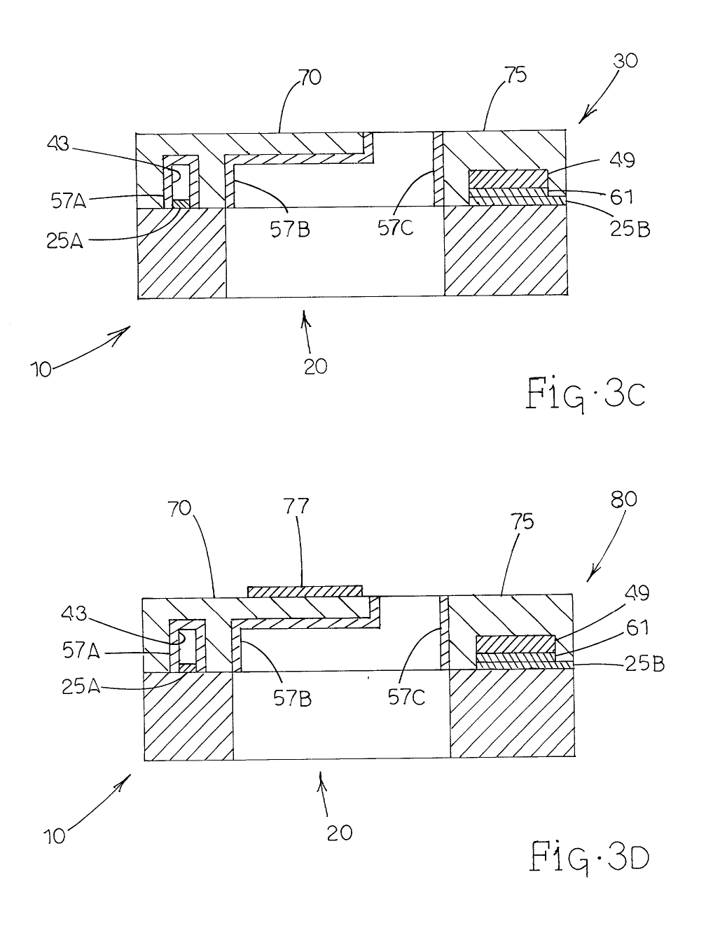

Referring now to FIGS. 1A-3D, a method for forming an optical MEMS device containing an integral optical aperture will now be described according to a first embodiment of the invention. This method generally comprises fabricating an optical aperture-containing wafer or substrate (FIGS. 1A-1B), fabricating a microstructure-containing wafer or substrate (FIGS. 2A-2I), and bonding the two substrates together as well as performing appropriate finishing steps (FIGS. 3A-3D).

Referring now to FIG. 1A, a first substrate, generally designated 10, is provided that has a first side, generally designated 12, and a second side, generally designated 14. An optical aperture, generally designated 20, is formed through first substrate 10 by performing an appropriate removal process such as etching. The particular removal process selected will depend in part on the composition of first substrate 10. For example, optical aperture 20 can be formed by ultrasonic etching. Because optical aperture 20 provides the conduit through which light passes through first substrate 10, first substrate 10 can be composed of any number of different materials typically utilized in MEMS or IC fabrication. Non-limiting examples of materials suitable for first substrate 10 include glass, quartz, sapphire, zinc oxide, silicon (in single-crystal, polycrystalline or amorphous forms), silica, alumina, or one of the various Group III-V compounds in either binary, ternary or quaternary forms (e.g., GaAs, InP, GaN, AlN, AlGan, InGaAs, and so on).

Referring to FIG. 1B, a conductive layer is deposited on second side 14 of first substrate 10. The conductive layer is then patterned by using a conventional photolithography masking technique to form one or more interconnects 25A and 25B. Non-limiting examples of materials suitable for the conductive layer include various metals and polysilicon. In the case of a metal layer, a lift-off patterning technique can be employed. The photoresist material used in the masking step and the unwanted portions of the conductive layer can be removed by, for example, immersion in a solvent bath. Depending upon the type of metal deposited to form the conductive layer, an adhesion layer of appropriate composition may be required. For example, if gold is chosen for interconnects 25A and 25B, a chromium or titanium (or an alloy such as titanium-tungsten) adhesion layer can be applied in preparation for the deposition of the conductive layer. If first substrate 10 is a conductive or semiconductive substrate, a non-conductive layer will be required between first substrate 10 and conductive interconnects 25A and 25B.

Referring to now to FIG. 2A, a second substrate, generally designated 30, is provided for the fabrication of a microstructure such as an optical shutter. Second substrate 30 has a first side, generally designated 32, and a second side, generally designated 34. Preferably, second substrate 30 includes a layer or region that can function as a built-in or electrochemical etch-stop. For example, second substrate 30 can comprise first and second bulk layers 30A and 30B that are separated by a buried oxide (e.g., silicon dioxide) or other type of insulating layer functioning as an etch-stop layer 30C. Accordingly, an example of a suitable second substrate 30 is a silicon-on-insulator (SOI) wafer. Another example is a heterostructure comprising a silicon base layer (i.e., second bulk layer 30B) on which an oxide etch-stop layer 30C is deposited or otherwise formed, and in turn on which an epitaxial silicon layer (i.e., first bulk layer 30A) is grown. As another alternative, first and second bulk layers 30A and 30B could be fusion bonded together, using etch-stop layer 30C as the interface material. As shown in FIG. 2A, first and second masking layers 36A and 36B of a dielectric material of suitable composition are respectively deposited on the outer major surfaces of second substrate 30 to protect portions of second substrate 30 during a subsequent etching step. One example of a suitable dielectric masking material is silicon nitride deposited by low-pressure chemical vapor deposition.

Referring to FIG. 2B, second masking layer 36B is patterned using a second photolithography mask. The patterning step could entail, for example, a dry etching technique such as plasma etching. As an alternative, first and second masking layers 36A and 36B could be composed of silicon oxide, in which case a reactive ion etching technique might be preferred in this patterning step.

Referring to FIG. 2C, an etching step is performed on second side 34 of second substrate 30 to define first and second pedestals 41A and 41B, an interconnect channel 43 between first and second pedestals 41A and 41 B, and a cavity 45. Wet or dry etching can be employed. Preferably, an anisotropic etching technique is selected for this step. In the case where oxide masks are formed, DRIE is preferred.

Referring to FIG. 2D, second masking layer 36B is stripped, and a dielectric layer 47 is conformally deposited on the exposed surfaces of second side 34 of second substrate 30. Dielectric layer 47 serves as a masking layer for a subsequent doping step, and preferably is an oxide or nitride.

Referring to FIG. 2E, another photolithographic technique is performed, and dielectric layer 47 is patterned (such as by plasma etching) to form a mask that defines an exposed area 47A on second substrate 30. A contact region 49 is then defined in second substrate 30 by a doping technique suitable for rendering contact region 49 electrically conductive and facilitating the formation of an ohmic contact. An example of a suitable doping technique entails depositing a dopant-containing gas on exposed area 47A to implant the desired concentration of the selected dopant. Examples of suitable gases include an arsenic-containing gas (e.g., arsine) or a phosphorus-containing gas (e.g., phosphine) when n-type doping is desired, or a boron-containing gas (e.g., diborane) when p-type doping is desired. Other examples of techniques for doping exposed area 47A are ion implantation or diffusion of doping species originating from a solid source.

Referring to FIG. 2F, dielectric layer 47 is stripped and a photoresist layer 53 deposited in its place. Photoresist layer 53 is then patterned to provide a mask defining an exposed area 53A on second substrate 30 for the subsequent etching of the microstructure. Other suitable masking materials for layer 53 are oxide, silicon nitride, or other common masking materials. If DRIE is used to etch exposed area 53A, a photoresist, oxide, or combination of the two would provide adequate masking as layer 53. If wet etching with KOH, EDP, or TMAH are applied, suitable masking layers such as silicon nitride would be required for layer 53. First masking layer 36A is also removed. Referring to FIG. 2G, exposed area 53A is then etched, such as by DRIE, down to etch-stop layer 30C. Photoresist layer 53 is then stripped.

Referring to FIG. 2H, another dielectric layer is conformally deposited on the exposed surfaces of second side 34 of second substrate 30. One example of a suitable dielectric material is a nitride, such as silicon nitride, that is deposited by low-pressure chemical vapor deposition. The dielectric layer is then patterned to define dielectric portions 57A, 57B and 57C, thereby exposing a portion of etch-stop layer 30C and the outermost surfaces of second side 34 of second substrate 30 that will serve as bonding areas in a subsequent bonding step described hereinbelow. When fabricating a microstructure from second substrate 30 in the form of an electrostatically actuated optical shutter, dielectric portions 57A, 57B and 57C can provide not only dielectric isolation, but also electrostatic force enhancement and pull-in voltage reduction.

Referring to FIG. 2I, an additional photolithography is performed, and a metal layer is deposited and patterned so as to form a conductive contact 61 on contact region 49. The composition of metal contact 61 is preferably gold, but could also be silver, copper, or aluminum, with an adhesive layer if needed or desired.

Referring now to FIG. 3A, first and second substrates 10 and 30 are aligned and bonded together at their respective second sides 14 and 34 by a suitable bonding technique such as anodic bonding, fusion bonding, glass-frit bonding, eutectic bonding, or adhesive bonding. The particular bonding technique selected will depend in part on the respective compositions of first and second substrates 10 and 30, and on the effect the bonding temperature might have on metal elements 25A, 25B, and 61. As a result of this bonding step, interconnect 25A is electrically isolated in interconnect channel 43 by dielectric portion 57A, while dielectric portions 57B and 57C isolate the sidewalls of second substrate 30. In addition, interconnect 25B electrically communicates with contact 61. Dielectric portion 57C isolates interconnect 25B and contact 61.

Referring to FIG. 3B, first bulk layer 30A of second substrate 30 is removed by etching, using an etchant such as KOH, to expose the top surface of etch-stop layer 30C. Referring to FIG. 3C, etch-stop layer 30C is removed by etching, thereby forming an actuatable, movable microstructure 70, such as an optical shutter, from second substrate 30 that is released from an electrode portion 75 of second substrate 30. Examples of suitable etchants include HF in the case where second substrate 30 was provided as an SOI wafer, and acetic acid:nitric acid:HF (8:3:1) in the case where second substrate 30 was provided as an n⁻ Si/p⁺ etch-stop/n⁻ Si stacked heterostructure.

Referring to FIG. 3D, masking, deposition, and etching steps are performed to form a metal (e.g., gold) element 77 on microstructure 70. At this point, the basic process for fabricating an optical MEMS device, generally designated 80, is complete, with the fabrication of optical aperture 20 having been an integral step of the process.

The structural material constituting microstructure 70 of optical MEMS device 80 semiconductive or conductive, and thus can be energized to effect movements of microstructure 70 so as to interact with an optical signal directed through aperture 20. The interaction can include attenuation of the signal and/or full ON/OFF switching function. Attenuation or full blocking of the signal can be effected by either absorbance or reflection. In the present embodiment, metal element 77 disposed on the top surface of microstructure 70 can serve as a mirror for reflection of the optical signal. Depending on the specific actuating method to be integrated into optical MEMS device 80, the movement of microstructure could be either in-plane or out-of-plane. Interconnect 25B communicates with contact 61, so as to define an actuation electrode that can be used to drive the movement of microstructure 70 by electrostatic force. Other methods of actuation can be employed as described below. Conformally deposited dielectric portions 57A, 57B, and 57C serve to isolate microstructure 70, electrode portion 75, and interconnects 25A and 25B from each other, and thus prevent shorting or shunting during actuation. Interconnect 25A is fully isolated in interconnect channel 43, and thus can function independently of microstructure 70, such as by serving as a conductor to some other element of the wafer assembly upon which microstructure 70 is formed.

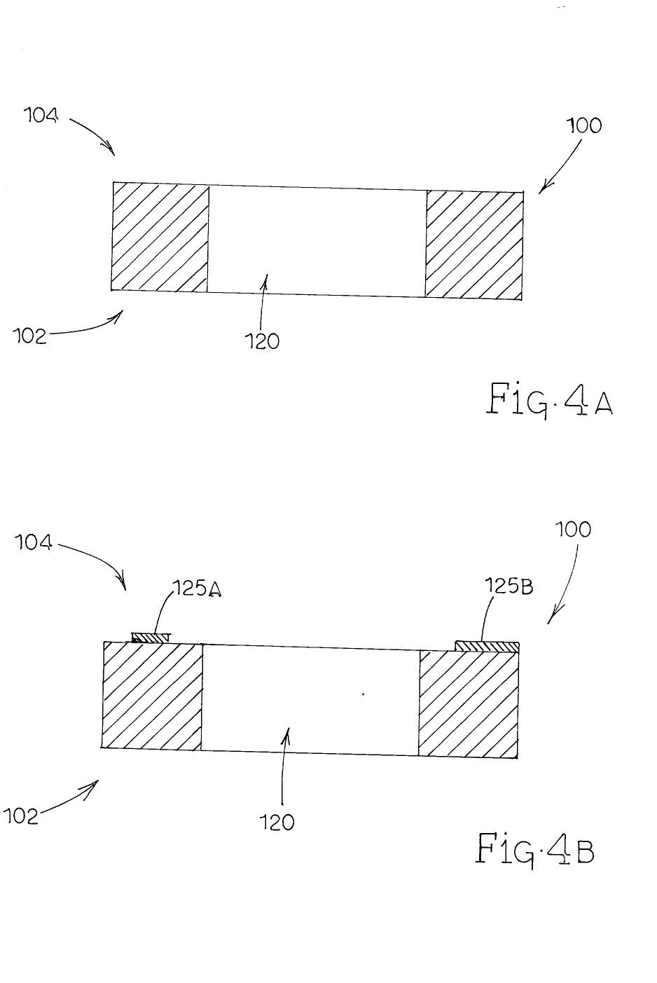

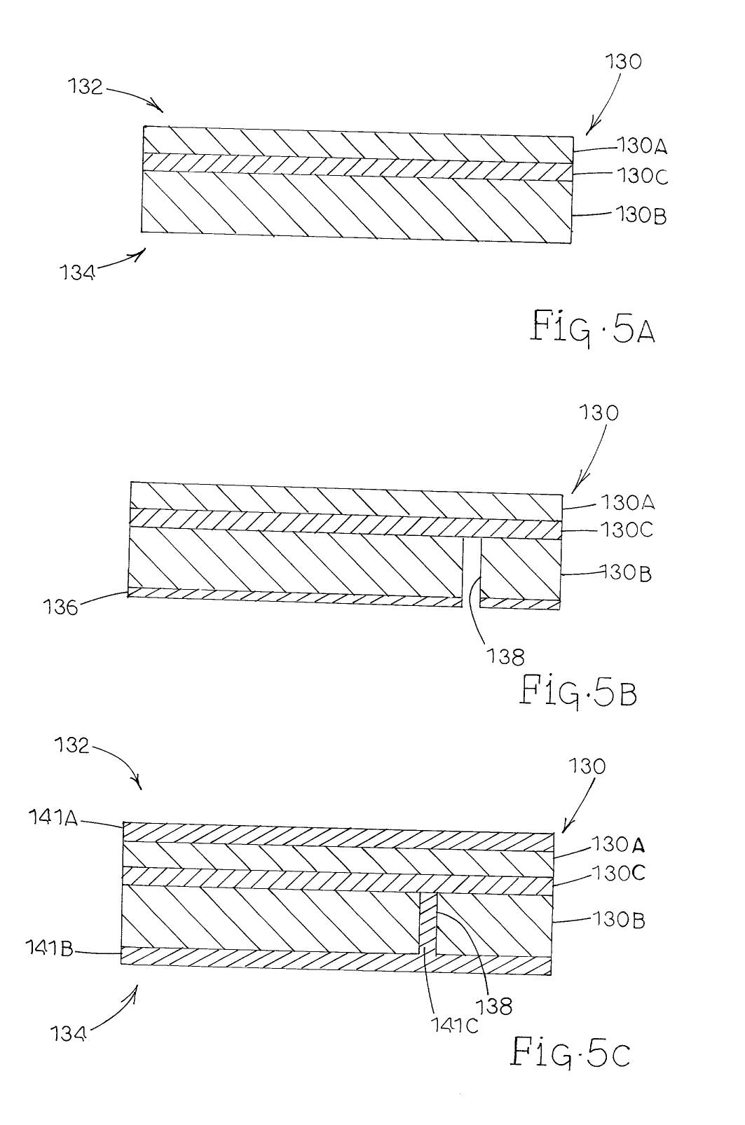

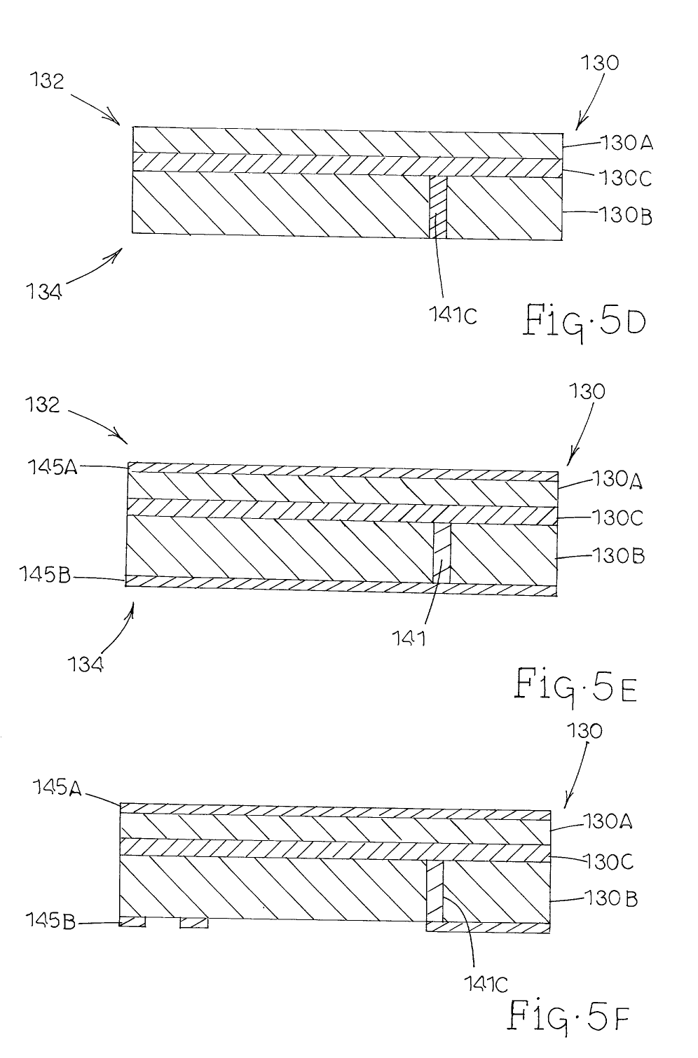

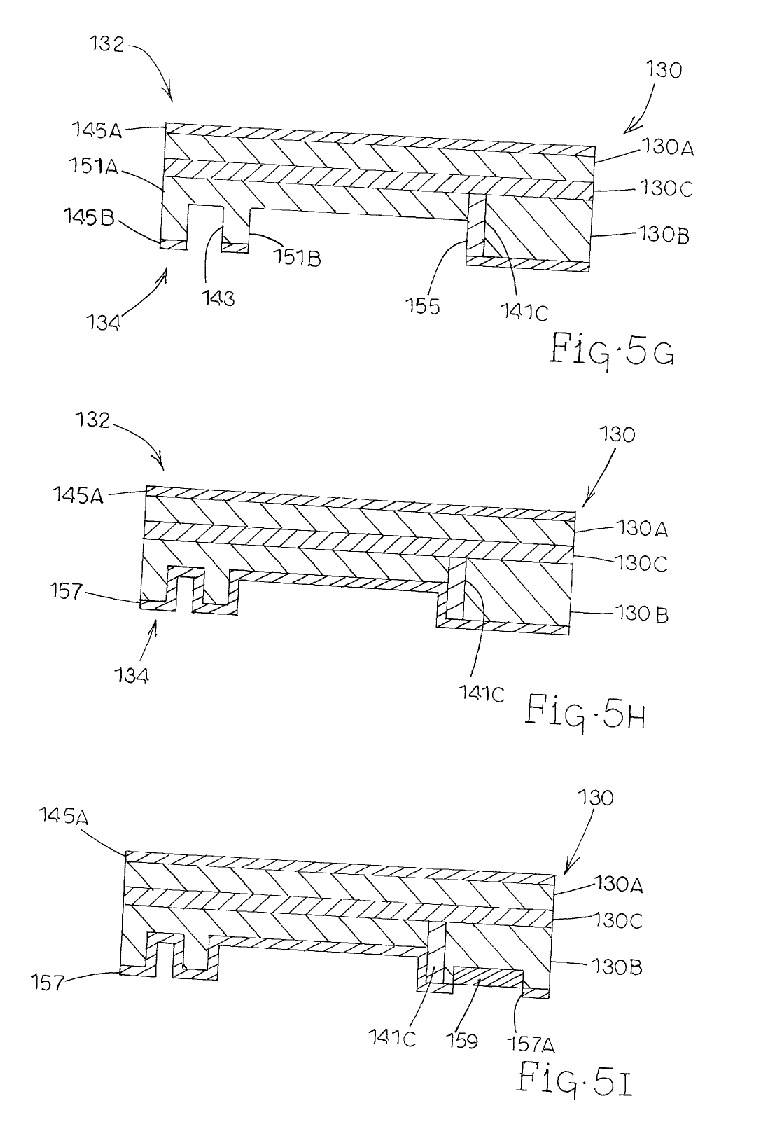

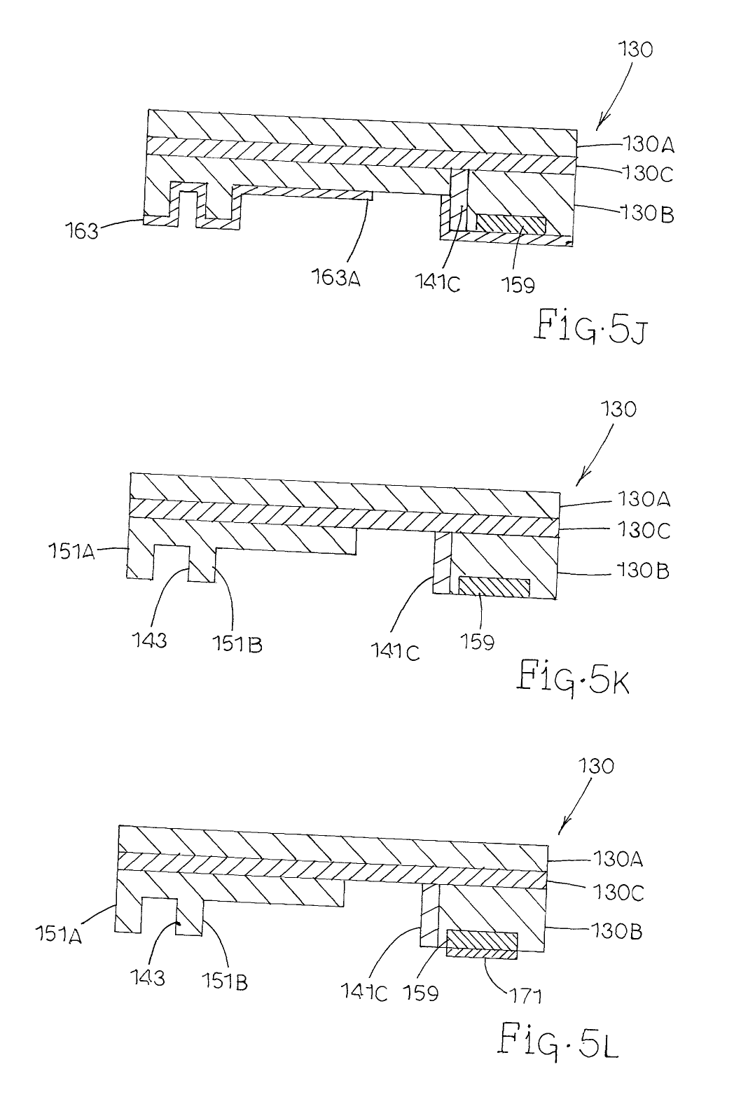

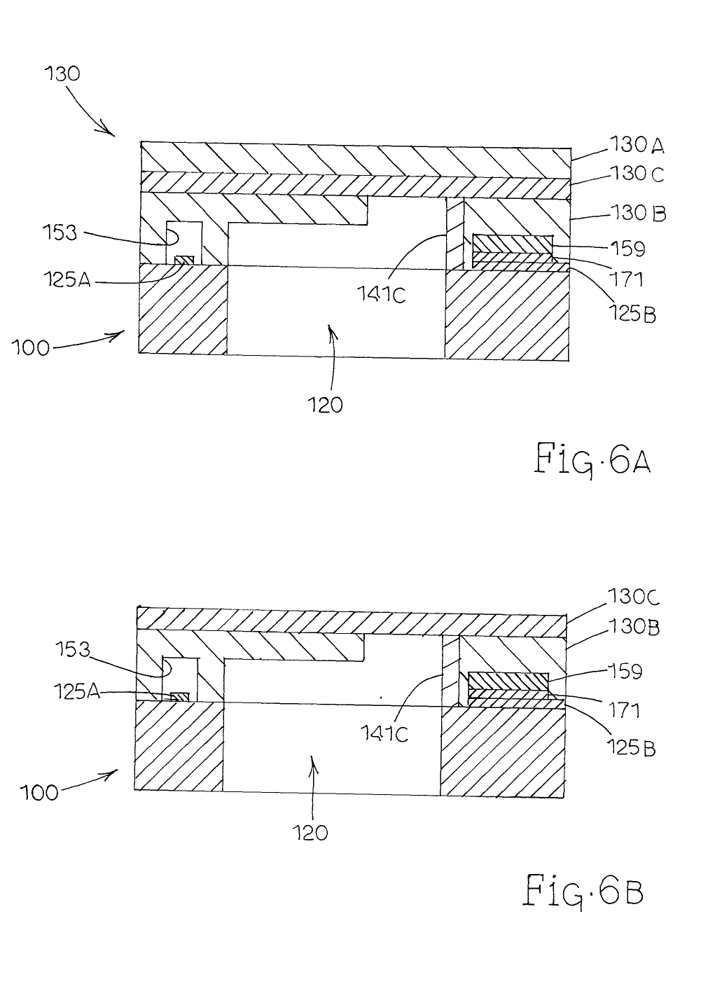

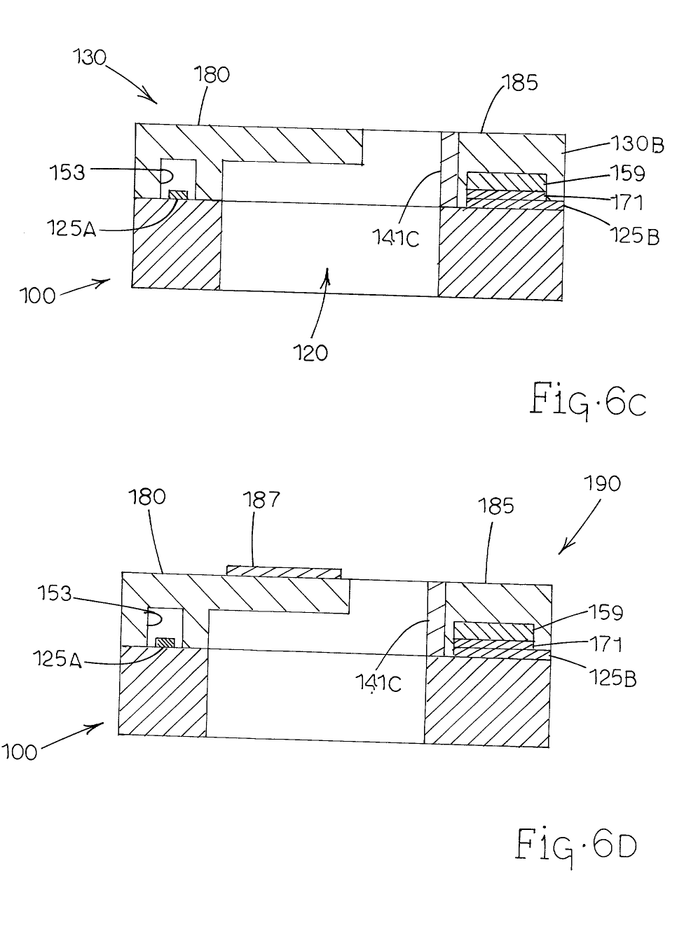

Referring now to FIGS. 4A-6D, a method for forming an optical MEMS device containing an integral optical aperture will now be described according to a second embodiment of the invention. This method generally comprises fabricating an optical aperture-containing wafer or substrate (FIGS. 4A to 4B), fabricating a microstructure-containing or substrate (FIGS. 5A to 5L), and bonding the two substrates together as well as performing other appropriate finishing steps (FIGS. 6A to 6D).

Referring now to FIG. 4A, a first substrate, generally designated 100, is provided that has a first side, generally designated 102, and a second side, generally designated 104. An optical aperture, generally designated 120, is formed through first substrate 100 by performing an appropriate removal process such as etching. The particular removal process selected will depend in part on the composition of first substrate 100. For example, optical aperture 120 can be formed by ultrasonic etching. Because optical aperture 120 provides the conduit through which light passes through first substrate 100, first substrate 100 can be composed of any number of different materials typically utilized in MEMS or IC fabrication. Non-limiting examples of materials suitable for first substrate 100 include glass, quartz, sapphire, zinc oxide, silicon, silica, alumina, or one of the various Group III-V compounds in either binary, ternary or quaternary forms (e.g., GaAs, InP, GaN, AlN, AlGan, InGaAs, and so on).

Referring to FIG. 4B, a conductive layer is deposited on second side 104 of first substrate 100. The conductive layer is then patterned by using a conventional photolithography masking technique to form one or more interconnects 125A and 125B. An alternative approach is to use a metal lift-off process where the photoresist material is first deposited and patterned. The conductive layer is deposited over the patterned photoresist, which is subsequently removed. This process will form the same conductive interconnects 125A and 125B. Non-limiting examples of materials suitable for the conductive layer include various metals and polysilicon. In the case of a metal layer, a lift-off patterning technique can be employed. The photoresist material used in the masking step and the unwanted portions of the conductive layer can be removed by, for example, immersion in a solvent bath. Depending upon the type of metal deposited to form the conductive layer, an adhesion layer of appropriate composition may be required. For example, if gold is chosen for interconnects 125A and 125B, a chromium or titanium (or an alloy such as titanium-tungsten) adhesion layer can be applied in preparation for the deposition of the conductive layer. If first substrate 100 is a conductive or semiconductive substrate, a non-conductive layer will be required between first substrate 100 and conductive interconnects 125A and 125B.

Referring to now to FIG. 5A, a second substrate, generally designated 130, is provided for the fabrication of a microstructure such as an optical shutter. Second substrate 130 has a first side, generally designated 132, and a second side, generally designated 134. Preferably, second substrate 130 includes a layer or region that can function as a built-in or electrochemical etch-stop. For example, second substrate 130 can comprise first and second bulk layers 130A and 130B that are separated by a buried oxide (e.g., silicon dioxide) or other type of insulating layer functioning as an etch-stop layer 130C. Accordingly, an example of a suitable second substrate 130 is a silicon-on-insulator (SOI) wafer. Another example is a heterostructure comprising a silicon base layer (i.e., second bulk layer 130B) on which an oxide etch-stop layer 130C is deposited or otherwise formed, and in turn on which an epitaxial silicon layer (i.e., first bulk layer 130A) is grown. As another alternative, first and second bulk layers 130A and 130B could be fusion bonded together, using etch-stop layer 130C as the interface material.

Referring to FIG. 5B, a masking layer 136 of a suitable composition is deposited on second side 134 of second substrate 130, and is patterned using a second photolithography mask to define one or more areas for dielectric isolation. One example of a suitable dielectric masking material is silicon nitride deposited by low-pressure chemical vapor deposition. One or more trenches 138 are then etched into second bulk layer 130B of second substrate 130 using a deep silicon etching technique until etch-stop layer 130C is reached.

Referring to FIG. 5C, trenches 138 are filled with a dielectric material by performing an oxidation step, a conformal dielectric isolation step, a combination of these steps, or a conformal un-doped polycrystalline silicon step. As a result, dielectric layers 141A and 141B, and one or more dielectric plugs 141C, are defined.

Referring to FIG. 5D, dielectric layer 141A formed or deposited on first side 132 of second substrate 130 and dielectric layer 141B formed or deposited on second side 134 are then removed, leaving only the dielectric plug or plugs 141C in trench or trenches 138. Referring to FIG. 5E, first and second masking layers 145A and 145B of a dielectric material of suitable composition (e.g., LPCVD nitride) are respectively deposited on the outer major surfaces (i.e., first and second sides 132 and 134) of second substrate 130 to protect portions of second substrate 130 during a subsequent etching step. Referring to FIG. 5F, second masking layer 145B is patterned using a second photolithography mask and a suitable etching process.

Referring to FIG. 5G, an etching step is performed to define first and second pedestals 151A and 151B, an interconnect channel 143 between first and second pedestals 151A and 151B, and a cavity 155. Wet or dry etching can be employed. Preferably, an anisotropic etching technique is selected for this step. In the case where oxide masks are formed, DRIE is preferred.

Referring to FIG. 5H, second masking layer 145B is stripped, and a dielectric layer 157 is conformally deposited on the exposed surfaces of second side 134 of second substrate 130. Dielectric layer 157 serves as a masking layer for the subsequent doping step, and preferably is an oxide or nitride.

Referring to FIG. 51, another photolithographic step is performed, and dielectric layer 157 is patterned (such as by plasma etching) to form a mask that defines an exposed area 157A on second substrate 130. A contact region 159 is then defined in second substrate 130 by a doping technique suitable for rendering contact region 159 electrically conductive. An example of a suitable doping technique entails depositing a dopant-containing gas on exposed area 157A to implant the desired concentration of the selected dopant. Examples of suitable gases include an arsenic-containing gas (e.g., arsine) or a phosphorus-containing gas (e.g., phosphine) when n-type doping is desired, or a boron-containing gas (e.g., diborane) when p-type doping is desired. Other examples of techniques for doping exposed area 157A are ion implantation or diffusion of doping species originating from a solid source.

Referring to FIG. 5J, dielectric layer 157 material is stripped and a photoresist layer 163 deposited in its place. Photoresist layer 163 is then patterned in a suitable masking step to provide a mask defining an exposed area 163A on second substrate 130 for the subsequent etching of the microstructure. First masking layer 145A is also removed. Referring to FIG. 5K, exposed area 163A is then etched, such as by DRIE, down to etch-stop layer 130C. Photoresist layer 163 is then stripped.

Referring to FIG. 5L, an additional photolithography is performed and a conductive layer deposited and patterned, thereby forming a conductive contact 171 on contact region 159. The composition of conductive contact 171 is preferably gold, but could also be silver, copper, or aluminum, with an adhesion layer is needed or desired.

Referring now to FIG. 6A, first and second substrates 100 and 130 are aligned and bonded together at their respective second sides 104 and 134 by a suitable bonding technique such as anodic bonding, fusion bonding, glass-frit bonding, eutectic bonding, or adhesive bonding. The particular bonding technique selected will depend in part on the respective compositions of first and second substrate. As a result of this bonding step, interconnect 125A is electrically isolated in interconnect channel 153, and dielectric plug 141C isolates the sidewall of second substrate 130. In addition, interconnect 125B electrically communicates with contact 171.

Referring to FIG. 6B, first bulk layer 130A of second substrate 130 is removed by etching, using an etchant such as KOH. Referring to FIG. 6C, etch-stop layer 130C is removed by etching, thereby forming an actuatable, movable microstructure 180, such as an optical shutter, from second substrate 130 that is released from an electrode portion 185 of second substrate 130. Examples of suitable etchants include HF in the case where second substrate 130 was provided as an SOI wafer, and acetic acid:nitric acid:HF (8:3:1) in the case where second substrate 130 was provided as an n⁻ Si/p⁺ etch-stop/n⁻ Si stacked heterostructure.

Referring to FIG. 6D, masking, deposition, and etching steps are performed to form a metal (e.g., gold) element 187 on microstructure 180. At this point, the basic process for fabricating an optical MEMS device, generally designated 190, is complete, with the fabrication of optical aperture 120 having been an integral step of the process.

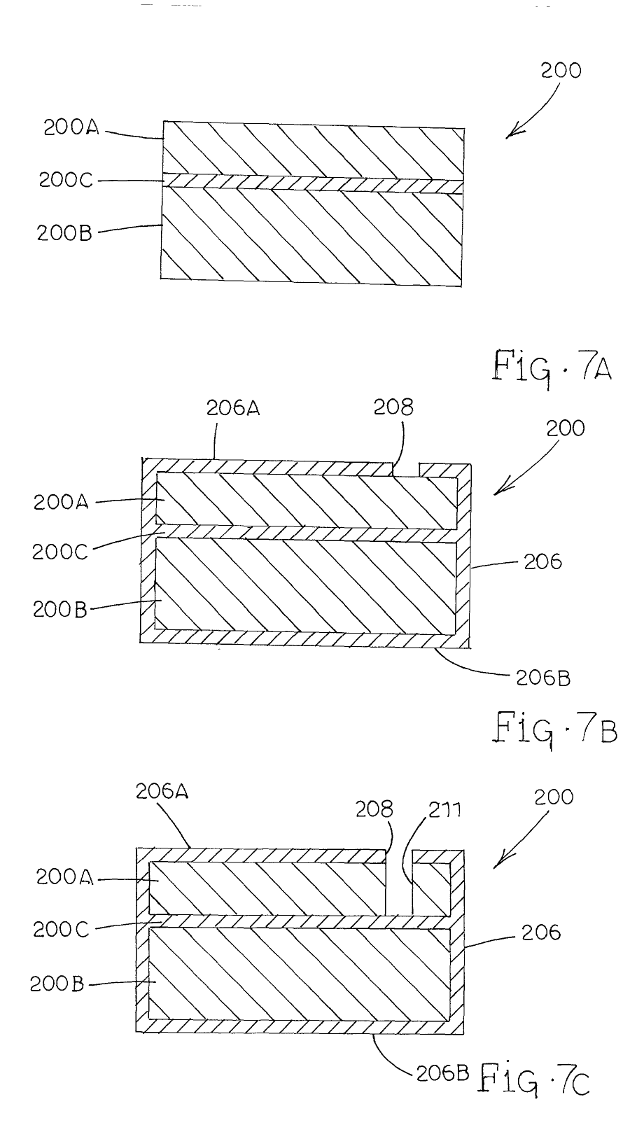

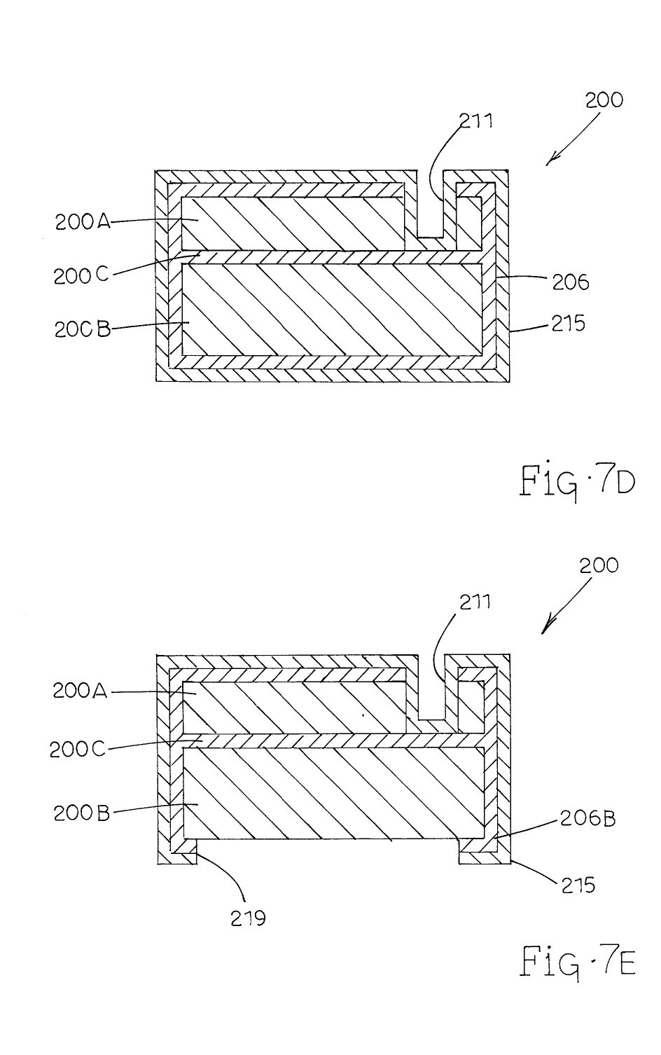

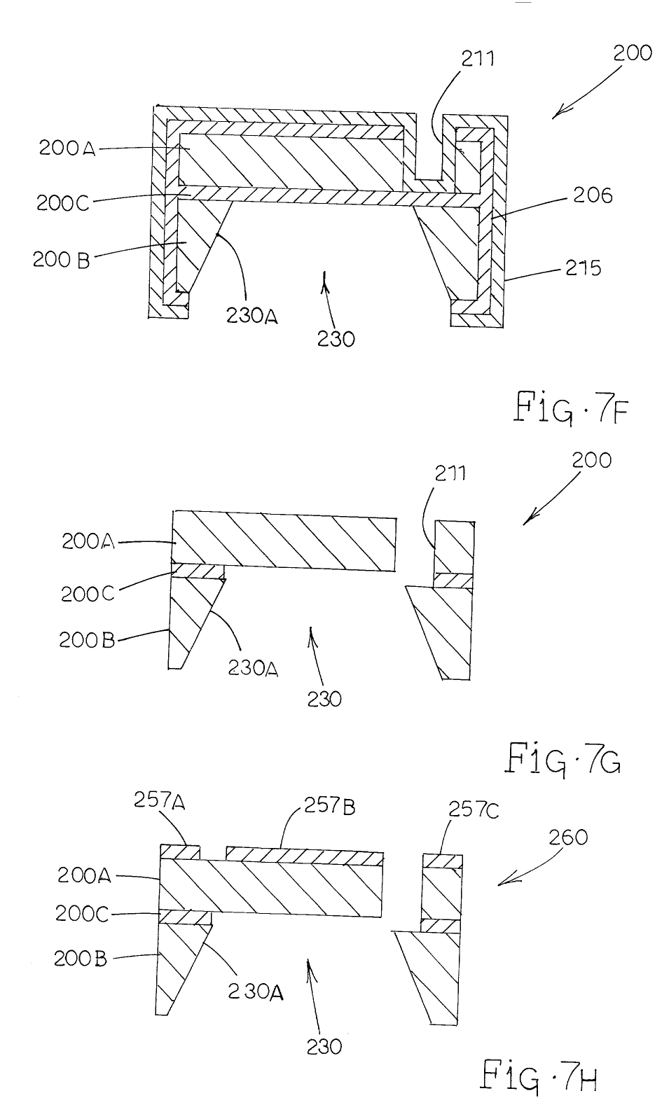

Referring now to FIGS. 7A-7H, a method for forming an optical MEMS device containing an integral optical aperture will now be described according to a third embodiment of the invention. This method differs from the other methods described hereinabove in part because it employs a single starting wafer to create the optical MEMS device, including its microstructure and associated optical aperture. Hence, referring to FIG. 7A, a substrate, generally designated 200, is provided that includes a layer or region that can function as a built-in or electrochemical etch-stop. For example, substrate 200 can comprise first and second bulk layers 200A and 200B that are separated by a buried oxide (e.g., silicon dioxide) or other type of insulating layer functioning as an etch-stop layer 200C. Accordingly, an example of a suitable substrate 200 is a silicon-on-insulator (SOI) wafer. Another example is a heterostructure comprising a silicon base layer (i.e., second bulk layer 200B) on which an oxide etch-stop layer 200C is deposited or otherwise formed (such as by thermal oxidation), and in turn on which an epitaxial silicon layer (i.e., first bulk layer 200A) is grown. As another alternative, first and second bulk layers 200A and 200B could be fusion bonded together, using etch-stop layer 200C as the interface material. First bulk layer 200A is used to form the microstructure, and second bulk layer 200B is used to form the optical aperture.

Referring to FIG. 7B, a masking material 206 is deposited on the surfaces of substrate 200 to protect portions of substrate 200 against subsequent etching steps. One example of a suitable dielectric masking material 206 is silicon nitride deposited by low-pressure chemical vapor deposition. An oxide film could alternatively be formed. Masking material 206 defines first and second masking layers 206A and 206B. First masking layer 206A is then patterned using a photo mask to create a window 208 that exposes an area of first bulk layer 200A.

Referring to FIG. 7C, an etching step is performed through window 208 to etch a trench 211 through first bulk layer 200A down to etch-stop layer 200C. Wet or dry etching can be employed. Preferably, an anisotropic etching technique is selected for this step to define vertical or near vertical sidewalls in trench 211. In the case where oxide masks are formed, DRIE is preferred.

Referring to FIG. 7D, a dielectric layer 215 is conformally deposited on the exposed surfaces of substrate 200, including trench 211. Dielectric layer 215 is preferably composed of an oxide or nitride. Referring to FIG. 7E, another photolithographic technique is performed from the backside of substrate 200 to pattern second masking layer 206B and dielectric layer 215 and thereby form a window 219 exposing second bulk layer 200B of substrate 200.

Referring to FIG. 7F, the backside is etched until etch-stop layer 200C is reached to define an optical aperture, generally designated 230. In the example shown in FIG. 7F, an etchant such as KOH, EDP, or TMAH has been used to etch selectively along the {111 } plane so as to create tapered aperture wall 230A. Referring to FIG. 7G, additional etching is performed in one or more steps to remove masking material 206, dielectric layer 215, and at least a central portion of etch-stop layer 200C. As a result, optical aperture 230 is fully defined, and an actuatable, movable microstructure 240, such as an optical shutter, is released.

Referring to FIG. 7H, masking, deposition, and etching steps are performed to form conductive elements 257A and 257B on microstructure 240, and 257C on the remaining portion of first bulk layer 200A of substrate 200. Conductive elements 257A and 257C can serve as electrodes or interconnects, and conductive element 257B can serve as a reflective surface. The composition of conductive elements 257A, 257B, and 257C is preferably gold, but could also be silver, copper, or aluminum, with an adhesive layer if needed or desired. At this point, the basic process for fabricating an optical MEMS device, generally designated 260, is complete, with the fabrication of optical aperture 230 having been an integral step of the process.

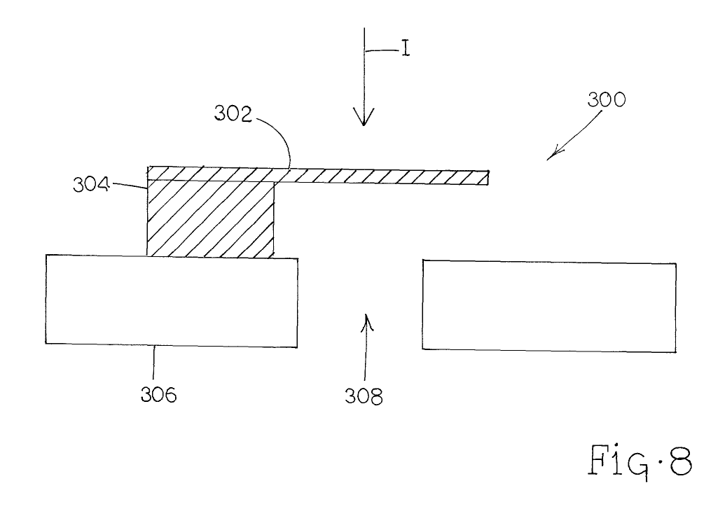

Referring now to FIG. 8, by way of example, a simplified illustration is made of an optical MEMS device, generally designated 300, that can be fabricated based on any of the methods described hereinabove. A microstructure comprising one or more optical shutters 302 is formed from a substrate or other bulk layer 304, such that each shutter 302 anchored to another substrate or bulk layer 306. One or more corresponding optical apertures, generally designated 308, are formed in substrate or bulk layer 306. Each shutter 302 is freely suspended over its corresponding aperture 308, and is movable by way of a suitable actuation assembly (not shown) and conductive elements built into optical MEMS device 300 such as those described hereinabove. Shutters 302 can be implemented as switches to selectively block or pass incident light I through aperture 308, or as variable optical attenuators (VOAs) to attenuate such light I. As described hereinabove, a reflective element can be added to the surface of each shutter 302 provided to block or attenuate light by means of reflection. In other cases, the material of shutter 302 serves to absorb light, or a thin film of known composition and optical properties is added to the surface of shutter 302 for this purpose.

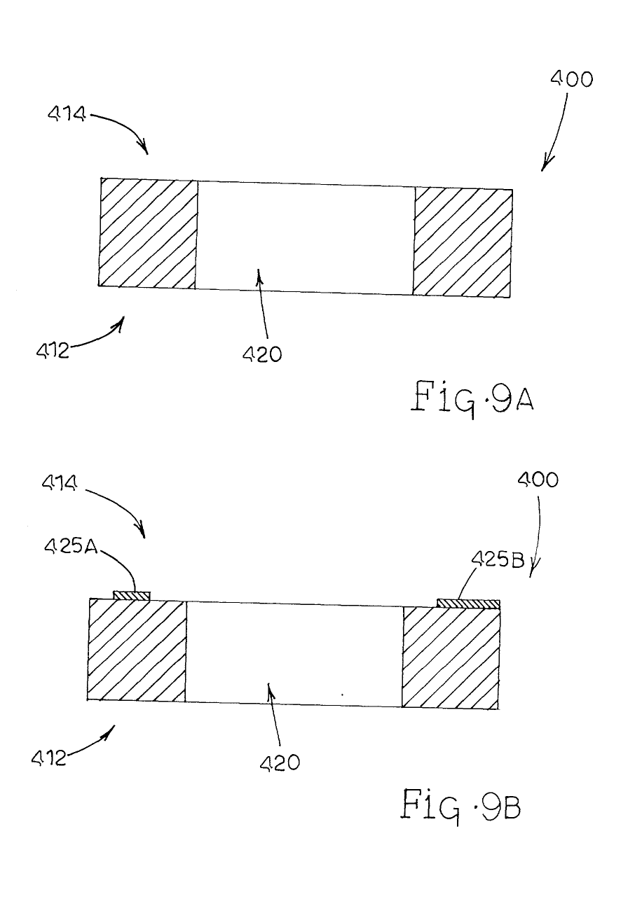

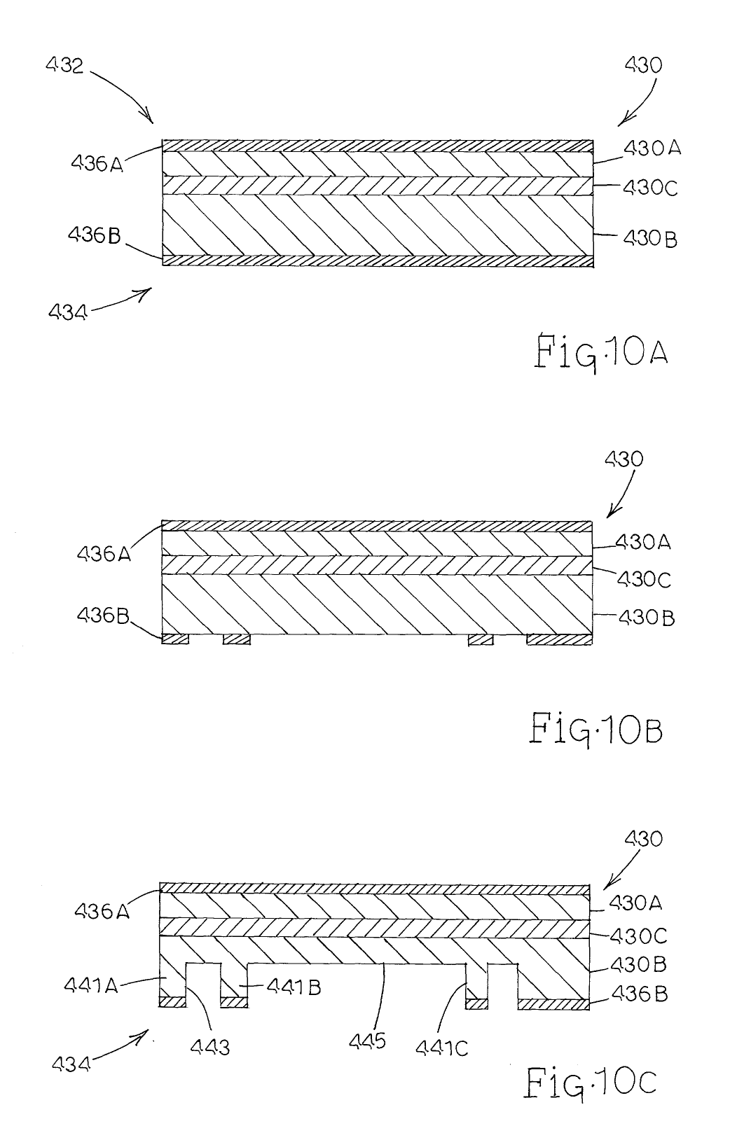

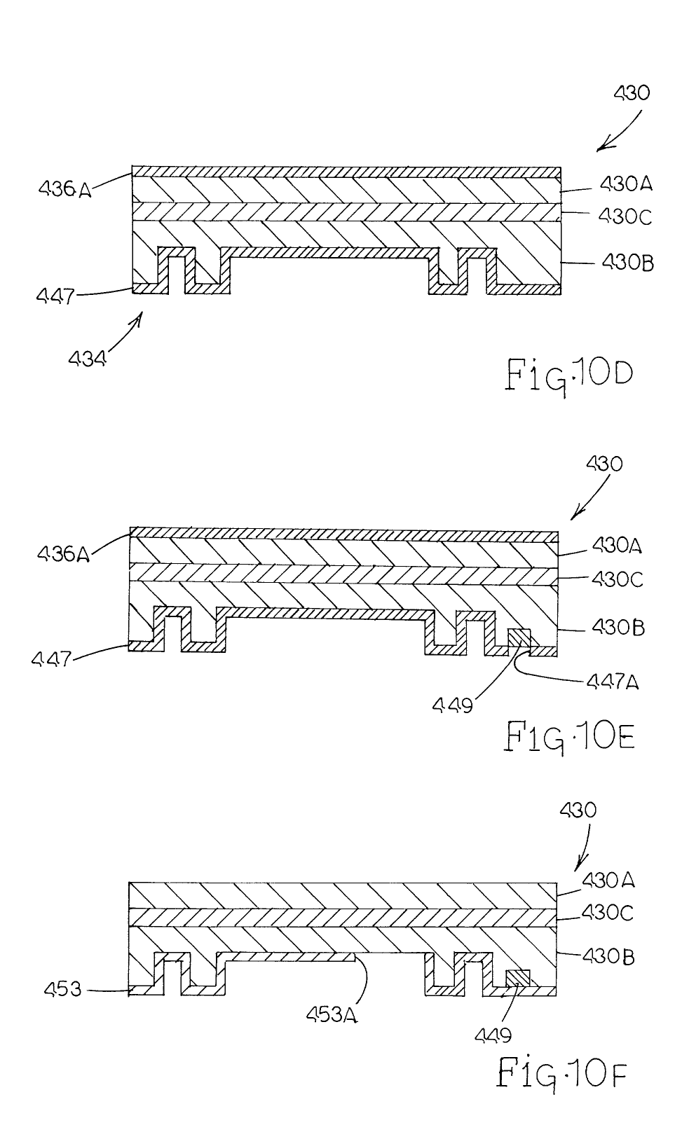

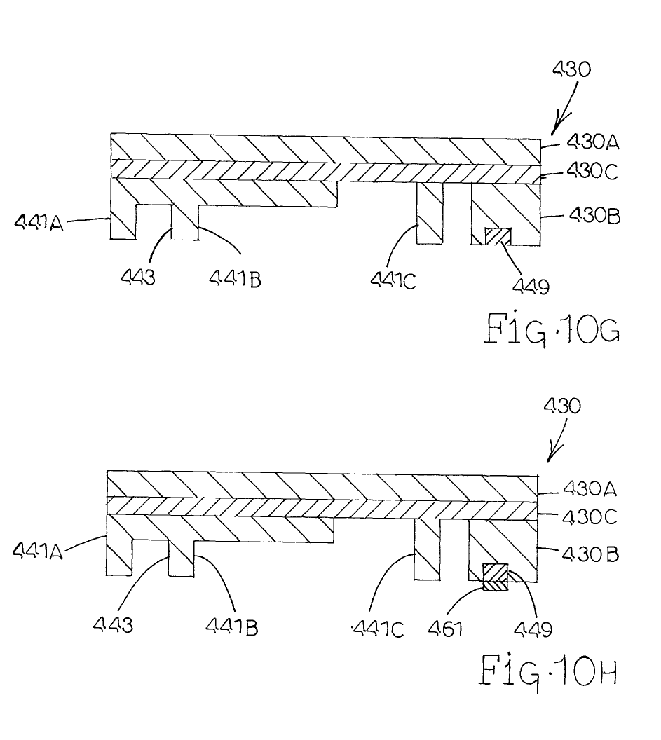

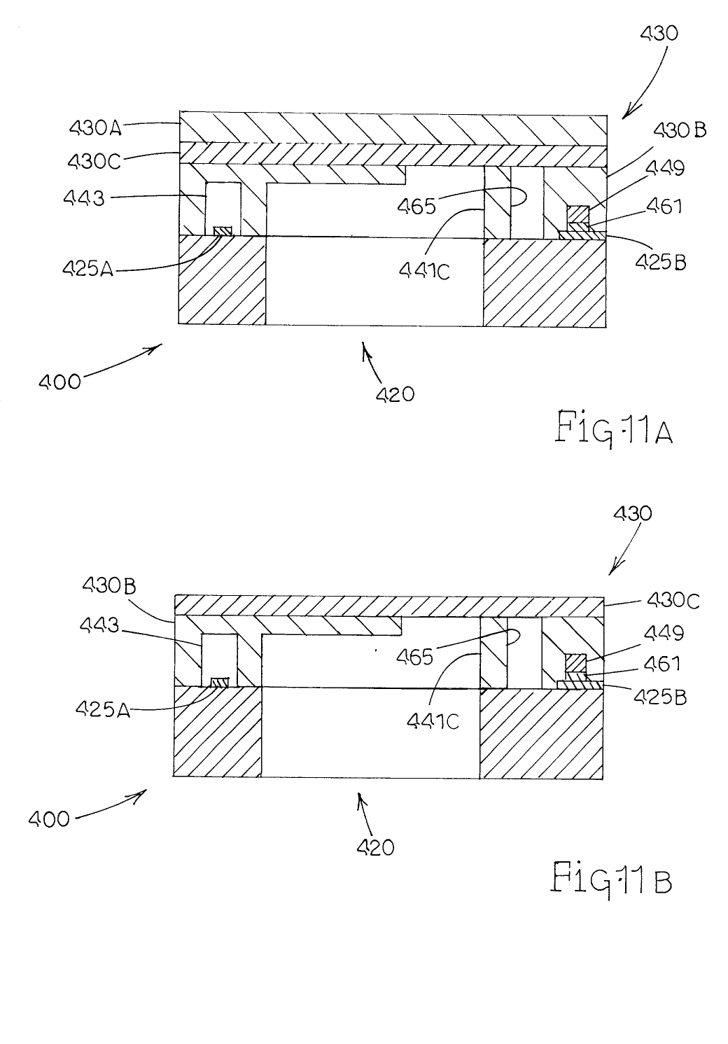

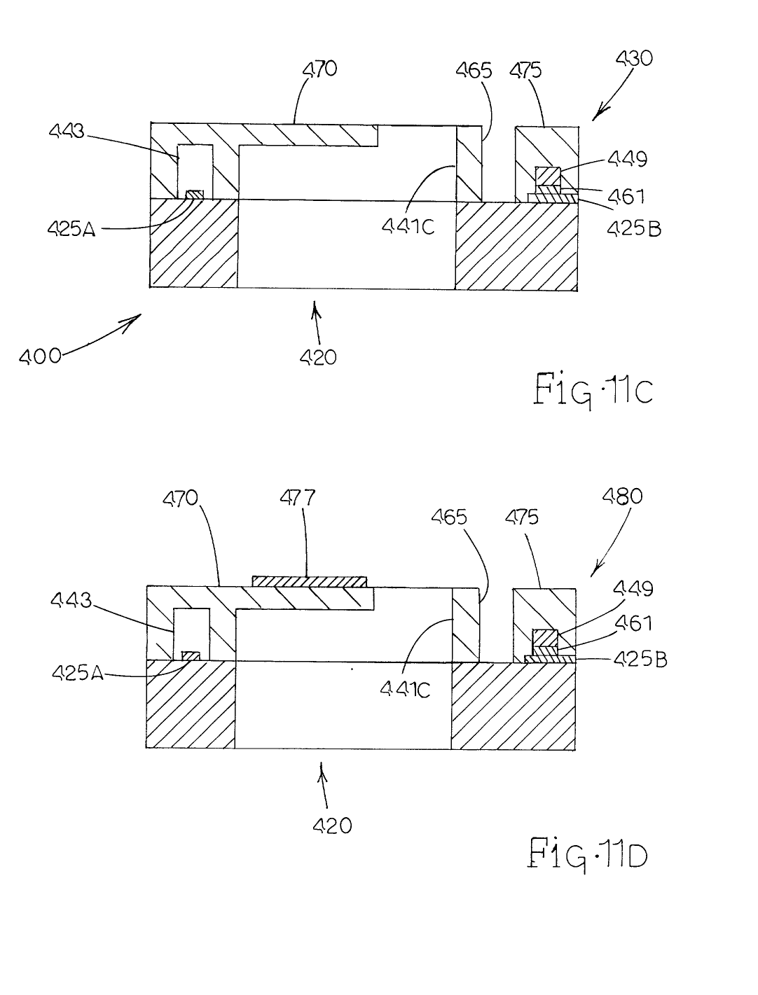

Referring now to FIGS. 9A-11D, another preferred method for forming an optical MEMS device containing an integral optical aperture, such as device 300 illustrated in FIG. 8, will now be described. This method generally comprises fabricating an optical aperture-containing wafer or substrate (FIGS. 9A-9B), fabricating a microstructure-containing wafer or substrate (FIGS. 10A-10H), and bonding the two substrates together as well as performing appropriate finishing steps (FIGS. 11A-11D).

Referring now to FIG. 9A, a first substrate, generally designated 400, is provided that has a first side, generally designated 412, and a second side, generally designated 414. An optical aperture, generally designated 420, is formed through first substrate 400 by preferably performing an ultrasonic etching step. Referring to FIG. 9B, a conductive layer is deposited on second side 414 of first substrate 400. The conductive layer is then patterned by using a conventional photolithography masking technique to form one or more interconnects 425A and 425B. Preferably, the conductive layer is composed of gold with a chromium adhesion layer.

Referring to now to FIG. 10A, a second substrate, generally designated 430, is provided for the fabrication of a microstructure such as an optical shutter. Second substrate 430 has a first side, generally designated 432, and a second side, generally designated 434. Preferably, second substrate 430 is an SOI structure or similar structure comprising first and second bulk layers 430A and 430B separated by a buried oxide (e.g., silicon dioxide) or other type of insulating layer functioning as an etch-stop layer 430C. As shown in FIG. 10A, first and second oxide masking layers 436A and 436B are respectively deposited on the outer major surfaces of second substrate 430 to protect portions of second substrate 430 during the following etching step. Referring to FIG. 10B, second masking layer 436B is patterned using a second photolithography mask and preferably a reactive ion etching technique.

Referring to FIG. 10C, an etching step (preferably DRIE) is performed on second side 434 of second substrate 430 to define first and second pedestals 441A and 441B, an interconnect channel 443 between first and second pedestals 441A and 441B, a cavity 445, and a third pedestal 441C. Referring to FIG. 10D, second masking layer 436B is stripped, and a dielectric layer 447 is conformally deposited on the exposed surfaces of second side 434 of second substrate 430. Dielectric layer 447 serves as a masking layer for a subsequent doping step, and preferably is composed of silicon nitride (e.g., Si₃N₄).

Referring to FIG. 10E, another photolithographic technique is performed, and dielectric layer 447 is patterned (such as by plasma etching) to form a mask that defines an exposed area 447A on second substrate 430. A contact region 449 is then defined in second substrate 430 by a suitable doping technique. Referring to FIG. 10F, dielectric layer 447 is stripped and a conformal oxide mask 453 is formed in its place. Oxide mask 453 defines an exposed area 453A on second substrate 430 for the subsequent etching of the microstructure. First masking layer 436A is also removed. Referring to FIG. 10G, exposed area 453A is then etched, preferably by DRIE, down to etch-stop layer 430C. Oxide mask 453 is then stripped. Referring to FIG. 10H, an additional photolithography is performed, and a gold layer is deposited and patterned so as to form a conductive contact 461 on contact region 449 with a chromium adhesion layer.

Referring now to FIG. 11A, first and second substrates 400 and 430 are aligned and bonded together at their respective second sides 414 and 434 by anodic bonding. As a result of this bonding step, interconnect 425A is electrically isolated in interconnect channel 443, and third pedestal 441C defines an isolation gap 465 that isolates interconnect 425B and contact 461. Depending on subsequent fabrication or packaging processes, isolation gap 465 may be filled with air or may be evacuated.

Referring to FIG. 11B, first bulk layer 430A of second substrate 430 is removed by etching (e.g., using an HF-based etchant), to expose the top surface of etch-stop layer 430C. Referring to FIG. 11C, etch-stop layer 430C is removed by etching, thereby forming an actuatable, movable microstructure 470, such as an optical shutter, from second substrate 430 that is released from an electrode portion 475 of second substrate 430. Referring to FIG. 11D, masking, deposition, and etching steps are performed to form a gold element 477 on microstructure 470 with a chromium adhesion layer. At this point, the basic process for fabricating an optical MEMS device, generally designated 480, is complete, with the fabrication of optical aperture 420 having been an integral step of the process.

In general, the actuation of shutters or other movable microstructures entails alternately displacing the shutter of a portion thereof out of the optical path to allow light to pass, and moving the shutter back into the optical path to interfere with the optical path. As appreciated by persons skilled in the art, the particular kinematics characterizing the shutter movement depend in part on the design of the actuation assembly that is to be integrated with the optical MEMS device. For instance, the shutter can translate either in-plane or out-of-plane. An example of in-plane movement is the translation of the shutter along a direction parallel with a linear array of apertures. Another example is the in-plane translation of the shutter along a direction perpendicular to the array of apertures. Yet another example is the in-plane translation of the shutter along an arcuate path. An example of out-of-plane movement is the rotation of the shutter about an axis parallel with the array of apertures. Another example is the out-of-plane rotation of the shutter about an axis perpendicular with the array of apertures. Such axes of rotation can be realized by, for example, a kinematic joint or a compliant, torsional hinge. Yet another example is the out-of-plane deflection (i.e., bending or curling) of the shutter, in which case the shutter is typically a bi-material composite with inherent residual stress and elastic mismatches.

As also appreciated by persons skilled in the art, a number of actuation modes are available for the above-described shutter kinematics. Electrostatic, thermal, and magnetic energy mechanisms can be utilized to implement in-plane parallel and perpendicular shutter movement. Electrostatic actuation can be implemented by means of comb drive, variable gap parallel-plate, variable are parallel-plate, or scratch drive designs. Thermal actuation can be implemented by means of a bent beam mechanism or pairs of geometric, thermally-mismatched structures. Magnetic actuation can be implemented by providing a coil on the shutter or a fixed coil on the substrate, both with an external magnetic field.

Electrostatic, thermal, and magnetic energy mechanisms can similarly be utilized to implement in-plane rotational shutter movement. Suitable electrostatic actuation designs include lateral zippers, angular comb drives, angular scratch drives, and variable gap parallel-plate designs. Thermal designs include the use of geometric thermal mismatched structures and offset antagonistic actuators relying on thermal expansion. Magnetic designs generally entail using a magnetic shutter and an external magnetic field.

Electrostatic, thermal, and magnetic energy mechanisms can also be utilized to implement out-of-plane rotational shutter movement. Electrostatic comb and scratch drives, as well as geometric thermal mismatch structures can be used, but in conjunction with appropriate linkages, pivots and pop-up levers to achieve the desired out-of-plane motion. Another suitable design effect thermal deformation of a polyimide joint attached to the shutter. Out-of-plane shutter motion can also be accomplished using an electromagnetic coil on the shutter in conjunction with an external magnetic field.

For shutters that are actuated by causing them to curl out-of-plane, electrostatic, thermal, magnetic, and piezoelectric energy mechanisms can be utilized. Parallel-plate electrostatic actuation can be used to pull an initially curled cantilever-type, bi-material shutter down to the substrate. The initial curl in the shutter is accomplished by taking advantage of residual film stresses in a bi-material shutter, or by plastically deforming the shutter through thermal heating. In a similar manner, an initially curled bimetallic shutter of cantilever beam design can be driven down to the substrate by taking advantage of Joule heating of the bimetallic layers. A cantilever beam made from a shape memory alloy (SMA) material could also be made to lay flat or curl out-of-plane by inducing Joule heating. Magnetic actuation can be used to pull an initially curled cantilever beam towards or away from the substrate through the interaction of an electromagnetic coil or magnetic material on the beam and an external magnetic field. Piezoelectric actuation can be used to control the curvature of a cantilever beam by taking advantage of the expansion of a piezoelectric material in a bimetallic system.

In addition, in-plane free shutter rotation can be achieved with electrostatics through the use of a stepper motor driven by a ratchet mechanism, and angular comb drive, or a rotary micromotor design with sidewall or substrate electrodes. The ratchet mechanism used to actuate the stepper motor can be driven by geometric, thermal mismatched structural pairs. The foregoing actuation methodologies are generally known to persons skilled in the art.

The substrates used to form optical apertures and microstructures according to the invention can be any size suitable for carrying out bulk micromachining processes. An example of a suitably sized starting wafer is approximately 100 mm or 150 mm in diameter and approximately 250 microns in thickness (or height).

The optical MEMS devices produced in accordance with the invention can be encapsulated or sealed in a suitable packaging process.

It will be understood that various details of the invention may be changed without departing from the scope of the invention. Furthermore, the foregoing description is for the purpose of illustration only, and not for the purpose of limitation—the invention being defined by the claims.

What is claimed is:

1. A method for fabricating an optical MEMS device comprising the steps of:
(a) providing a first substrate having a first side and an opposing second side;
(b) forming an aperture through the first substrate to enable an optical signal to be transmitted through the aperture along a path generally perpendicular to the first and second sides;
(c) forming a movable, actuatable microstructure on a second substrate; and
(d) bonding the second substrate to the first substrate, whereby the first and second substrates are aligned to enable the microstructure to interact with the optical signal upon actuation of the microstructure.

2. The method according to claim 1 wherein the first substrate is composed of a material selected from the group consisting of silicon, silica, glass, quartz, sapphire, zinc oxide, alumina, Group III-V compounds, and alloys thereof.

3. The method according to claim 1 wherein the step of forming the aperture comprises the step of performing an etching operation on the first substrate.

4. The method according to claim 1 wherein the step of forming the aperture comprises the step of forming a substantially vertical wall through the first substrate.

5. The method according to claim 1 wherein the step of forming the aperture comprises the step of forming a tapered wall through the first substrate.

6. The method according to claim 1 comprising the step of forming a conductive element on the first substrate.

7. The method according to claim 6 comprising the step of forming a channel in the second substrate whereby, after the bonding step, the conductive element formed on the first substrate is electrically isolated.

8. The method according to claim 1 wherein the second substrate comprises an etch-stop layer interposed between first and second bulk layers.

9. The method according to claim 8 comprising the step of removing at least a portion of the etch-stop layer to render the microstructure movable.

10. The method according to claim 1 comprising the step of doping a conductive region of the second substrate to enhance electrical conductivity of the conductive region.

11. The method according to claim 10 comprising the steps of forming a first contact on the second substrate in communication with the conductive region, and forming a second contact on the first substrate whereby, after the bonding step, the first contact communicates with the second contact.

12. The method according to claim 1 comprising the steps of forming a contact on the second substrate and a dielectric layer on a sidewall of the second substrate, whereby the contact is isolated from the microstructure.

13. The method according to claim 1 wherein at least a portion of the microstructure is freely suspended over the aperture.

14. The method according to claim 1 comprising the step of forming an optically reflective element on the microstructure.

15. The method according to claim 1 wherein the step of bonding comprises the step of performing a bonding technique selected from the group consisting of anodic bonding, fusion bonding, glass-frit bonding, eutectic bonding, and adhesive bonding.

16. An optical MEMS device fabricated according to the method of claim 1.

17. A method for fabricating an optical MEMS device comprising the steps of:
(a) providing a substrate comprising an etch-stop layer interposed between first and second bulk layers;
(b) forming a movable, actuatable microstructure in the first bulk layer;
(c) forming an aperture through the second bulk layer to enable an optical signal to be transmitted through the aperture along a path generally perpendicular to the substrate; and
(d) removing at least a portion of the etch-stop layer sufficient to release the microstructure, thereby enabling the microstructure to interact with the optical signal upon actuation of the microstructure.

18. The method according to claim 17 wherein the step of forming the aperture comprises the step of performing an etching operation on the second bulk layer of the substrate.

19. The method according to claim 17 wherein the step of forming the aperture comprises the step of forming a substantially vertical wall through the second bulk layer of the substrate.

20. The method according to claim 17 wherein the step of forming the aperture comprises the step of forming a tapered wall through the second bulk layer of the substrate.

21. The method according to claim 17 comprising the step of removing at least a portion of the etch-stop layer to render the microstructure movable.

22. The method according to claim 17 comprising the step of forming a conductive element on the first bulk layer of the substrate.

23. The method according to claim 17 comprising the step of forming an optically reflective element on the first bulk layer of the substrate.

24. An optical MEMS device fabricated according to the method of claim 17.

25. A method for fabricating an optical MEMS device comprising the steps of:
(a) providing a first substrate having a first side and an opposing second side;
(b) forming an aperture through the first substrate to enable an optical signal to be transmitted through the aperture along a path generally perpendicular to the first and second sides;
(c) forming a movable, actuatable microstructure from a second substrate;
(d) forming a conductive component on the second substrate;
(e) forming a gap in the second substrate to electrically isolate the conductive component from the microstructure; and
(f) bonding the second substrate to the first substrate, whereby the first and second substrates are aligned to enable the microstructure to interact with the optical signal upon actuation of the microstructure.

26. An optical MEMS device fabricated according to the method of claim 25.
